(19) United States
(12) Patent Application Publication
(10) Pub. No.: US 2013/0299853 A1
(43) Pub. Date: Nov. 14, 2013

(54) HIGH VOLTAGE LIGHT EMITTING DIODE AND FABRICATING METHOD THEREOF

(71) Applicant: CHI MEI LIGHTING THECHNOLOGY CORP., Tainan (TW)

(72) Inventors: Yen-Wei Chen, Tainan (TW); Lu-Shui Chu, Tainan (TW)

(73) Assignee: Chi Mei Lighting Thechnology Corp., Tainan (TW)

(21) Appl. No.: 13/887,750

(22) Filed: May 6, 2013

(30) Foreign Application Priority Data
May 8, 2012 (TW) 101116336

(51) Int. Cl. H01L 33/36

(52) U.S. Cl. CPC H01L 33/36
USPC 257/88; 438/14

(57) ABSTRACT

A method for fabricating a high voltage light emitting diode (HV LED) includes: calculating a total area of the HV LED according to a predetermined light emission luminance; calculating the number of sub-LEDs according to a predetermined operating voltage; subtracting, from the total area, areas of isolation trenches between the sub-LEDs, electrode areas and areas of series-connected conductive leads between the sub-LEDs, and then dividing the difference obtained through the subtraction by the number of the sub-LEDs, so as to calculate an effective light emission area of each of the sub-LEDs; and according to the effective light emission area, adjusting the area of a sub-LED having an electrode and the area of a sub-LED having no electrode, so as to enable the area of the sub-LED having an electrode to be greater than the area of the sub-LED having no electrode. An HV LED manufactured by the above method.

### CROSS-REFERENCE TO RELATED APPLICATIONS

This non-provisional application claims priority under 35 U.S.C. §119(a) on Patent Application No. 101116336 filed in Taiwan, R.O.C. on May 8, 2012, the entire contents of which are hereby incorporated by reference.

Some references, if any, which may include patents, patent applications and various publications, may be cited and discussed in the description of this invention. The citation and/or discussion of such references, if any, is provided merely to clarify the description of the present invention and is not an admission that any such reference is “prior art” to the invention described herein. All references listed, cited and/or discussed in this specification are incorporated herein by reference in their entireties and to the same extent as if each reference was individually incorporated by reference.

### FIELD OF THE INVENTION

The present invention relates to a light emitting diode (LED) and a fabricating method thereof, and more particularly to a high voltage LED (HV LED) and a fabricating method thereof.

### BACKGROUND OF THE INVENTION

The basic architecture of an HV LED is the same as that of an alternating current LED (AC LED), in which the chip area is partitioned into a plurality of series-connected sub-LEDs. The HV LED is characterized in that a chip of the HV LED can determine the number and the size of the series-connected sub-LEDs according to different input voltage demands of customers. Moreover, a single sub-LED may be optimized, so as to obtain preferable current distribution, thereby improving light emitting efficiency. The light emitting efficiency of the HV LED is superior to that of a conventional LED because the HV LED can not only be applied to a constant direct current environment, but also can be applied to an alternating current environment as long as the HV LED is externally connected to a bridge type current rectifier. Therefore, high flexibility is provided. In addition, compared with the AC LED, the HV LED has no light emission area of the internal bridge type current rectifier, so that the light emitting efficiency is relatively high, and the durability is also preferable. Moreover, the HV LED is designed with small current and a plurality of series-connected sub-LEDs, so the current can be diffused more evenly, thereby improving the light extraction efficiency.

FIG. 1A is a schematic view of a conventional HV LED 1. Sub-LEDs C1 to C16 of the HV LED 1 are connected in series sequentially. A P-type electrode is located on the sub-LED C1, and an N-type electrode is located on the sub-LED C16. The areas of the sub-LEDs C1 to C16 are the same. FIG. 1B shows an illuminating state of the conventional HV LED. As shown in the drawing, the sub-LEDs C1 and C16 have a P-type electrode and an N-type electrode respectively. A current barrier layer is generally manufactured below the P electrode to prevent the case that the current directly flows through the location below the P electrode and cannot be effectively diffused. Accordingly, when the sub-LEDs C1 and C16 are illuminated, the effective light emission area thereof decreases, and the current density increases. Therefore, the luminance of the sub-LEDs C1 and C16 is higher, which causes uneven light emission. In addition, the sub-LEDs C1 and C16 have larger current density when being illuminated, which resulting in a shorter service life of the sub-LEDs C1 and C16 comparing with that of other sub-LEDs C2 to C15.

However, the conventional HV LED cannot effectively solve problems such as uneven light emission and unequal chip lifetime caused by the uneven current density, so it is required to propose a novel HV LED, which may be used for averaging the current density, so as to improve the light emission evenness and prolong the chip lifetime.

### SUMMARY OF THE INVENTION

In one aspect, the present invention is directed to an method for fabricating a HV LED, which may average the current density so as to prolong the service life of the HV LED.

In one embodiment, the method includes: calculating a total area of the HV LED according to a predetermined light emission luminance; calculating a number of sub-LEDs according to a predetermined operating voltage; subtracting, from the total area, areas of isolation trenches between the sub-LEDs, electrode areas and areas of series-connected conductive leads between the sub-LEDs, and then dividing the difference obtained through the subtraction by the number of the sub-LEDs, so as to calculate an effective light emission area of each of the sub-LEDs; and according to the effective light emission area, adjusting an area of a sub-LED having an electrode and an area of a sub-LED having no electrode, so as to enable the area of the sub-LED having an electrode to be greater than the area of the sub-LED having no electrode.

In one embodiment, the electrode is a P-type electrode or an N-type electrode.

In one embodiment, the sub-LEDs are arranged in a matrix.

In one embodiment, the area of each of the sub-LEDs having no electrode minus the area of a series-connected conductive lead on the sub-LED is equal to the effective light emission area of the sub-LED.

In one embodiment, the effective light emission area of each of the sub-LEDs plus the area of a series-connected conductive lead on the sub-LED and the electrode area is equal to the adjusted area of the sub-LED having an electrode.

In one embodiment, all the sub-LEDs are connected in series to each other.

In one embodiment, the HV LED comprises a sub-LED having a P-type electrode and a sub-LED having an N-type electrode.

In another aspect, the present invention is directed to an HV LED, which is capable of averaging the current density so as to prolong the service life of the HV LED.

In one embodiment, an HV LED includes a plurality of sub-LEDs. The sub-LEDs include sub-LEDs having an electrode and sub-LEDs having no electrode. An area of a sub-LED having an electrode is greater than an area of a sub-LED having no electrode.

In one embodiment, the sub-LEDs are arranged in a matrix.

In one embodiment, the areas of the sub-LEDs having no electrode are equal.

In one embodiment, the area of a sub-LED having an electrode is equal to the sum of the area of a sub-LED having no electrode plus an area of the electrode.

In one embodiment, the HV LED includes a sub-LED having a P-type electrode and a sub-LED having an N-type electrode.

In one embodiment, all the sub-LEDs are connected in series to each other.

In one embodiment, the HV LED further includes isolation trenches between the sub-LEDs.

In one embodiment, the HV LED further includes series-connected conductive leads between the sub-LEDs.

In one embodiment, an area of each of the sub-LEDs is a geometric area, comprising a circular area or a polygonal area.

These and other aspects of the present invention will become apparent from the following description of the preferred embodiment taken in conjunction with the following drawings, although variations and modifications therein may be effected without departing from the spirit and scope of the novel concepts of the disclosure.

### BRIEF DESCRIPTION OF THE DRAWINGS

The accompanying drawings illustrate one or more embodiments of the invention and together with the written description, serve to explain the principles of the invention. Wherever possible, the same reference numbers are used throughout the drawings to refer to the same or like elements of an embodiment, and wherein:

FIG. 1A is a schematic view of a conventional HV LED 1;

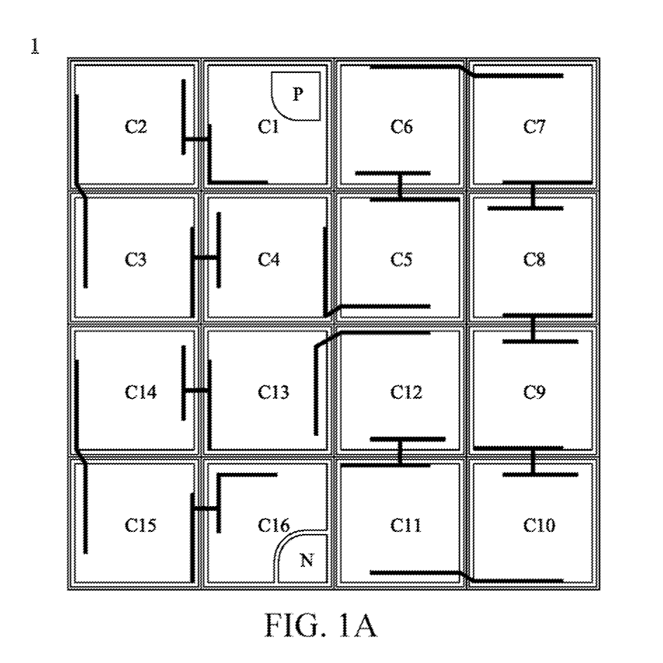

FIG. 1B shows an illuminating state of the conventional HV LED;

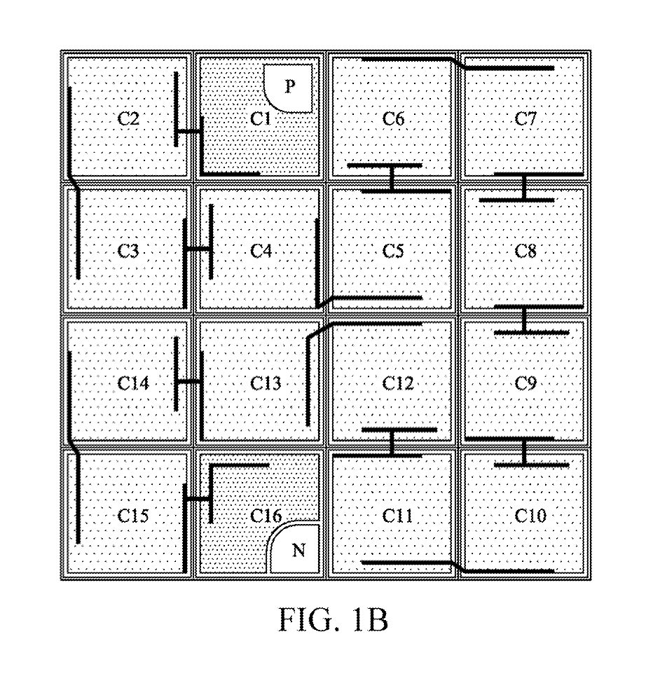

FIG. 2 shows an HV LED 2 according to an embodiment of the present invention; and

FIG. 3 is a flow chart showing a method for fabricating an HV LED according to an embodiment of the present invention.

### DETAILED DESCRIPTION OF THE INVENTION

The present invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

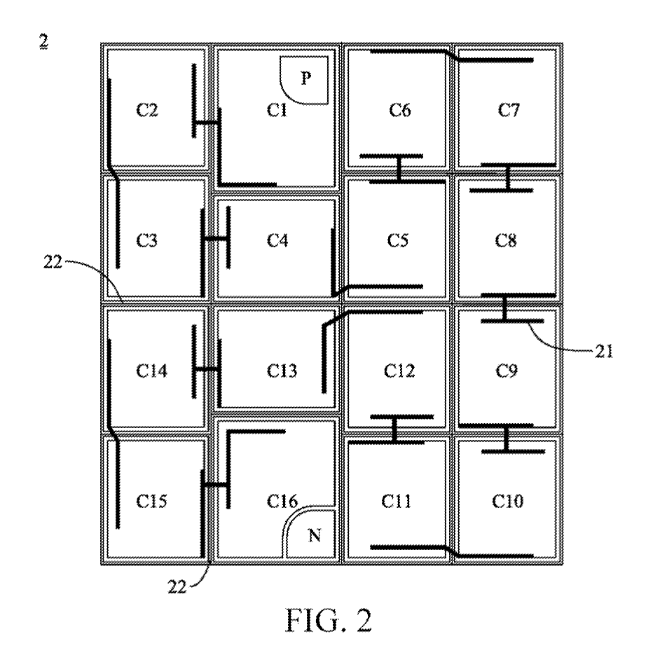

FIG. 2 shows an HV LED 2 according to an embodiment of the present invention. The HV LED 2 includes a plurality of sub-LEDs C1 to C16. Each of sub-LEDs C1 and C16 has an electrode. Sub-LEDs C2 to C15 have no electrode. The area of the sub-LEDs C1 and C16 having an electrode is greater than the area of the sub-LEDs C2 to C15 having no electrode. The aforementioned electrodes in the sub-LEDs C1 and C16 may be different conductive type electrodes. For example, the electrode of the sub-LED C1 can be a P-type electrode, and the electrode of the sub-LED C16 can be an N-type electrode. Alternatively, the electrode of the sub-LED C1 can be an N-type electrode, and the electrode of the sub-LED C16 can be a P-type electrode. Moreover, the electrode area of the electrodes of the sub-LEDs C1 and C16 may be a geometric area, and likewise, the area of each of the sub-LEDs may also be a geometric area. The geometric area includes a circular area or a polygonal area. The plurality of sub-LEDs C1 to C16 may be arranged in a matrix, but the present invention is not limited thereto. In this embodiment, the area of the sub-LEDs (such as C1 and C16) having an electrode is equal to the sum of the area of the sub-LEDs having no electrode plus the electrode area of the electrodes. Through such setting, the effective light emission areas of all the sub-LEDs are equal. In addition, all the sub-LEDs in the HV LED 2 are connected in series.

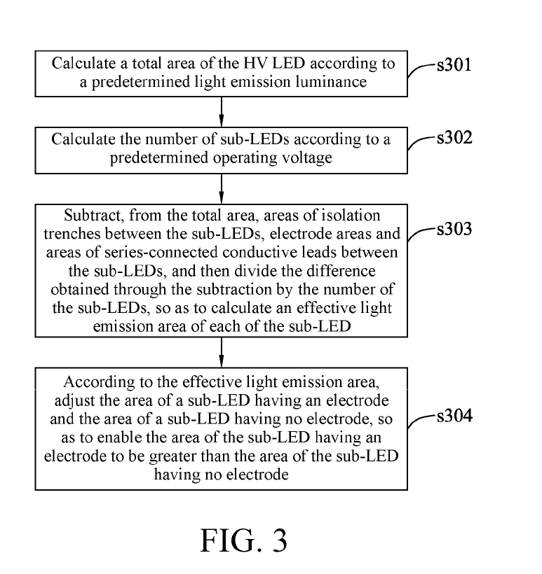

FIG. 3 is a flow chart showing a method for fabricating an HV LED according to an embodiment of the present invention. The method can be illustrated in combination with the HV LED 2 in FIG. 2. At first, according to a predetermined light emission luminance demand required by a customer, the total area of the HV LED 2 of this disclosure is defined (step s301). According to a predetermined operating voltage required by the customer, the number of sub-LEDs is designed and partitioned (step s302). Areas of isolation trenches 22 between the sub-LEDs, electrode areas and areas of series-connected conductive leads 21 between the sub-LEDs are subtracted from the total area of the HV LED 2, and then the difference obtained through the subtraction is divided by the number of the sub-LEDs, so as to calculate an effective light emission area of each of the sub-LEDs (step s303). Then, according to the effective light emission area of each sub-LED, the area of a sub-LED having an electrode and the area of a sub-LED having no electrode are adjusted, so as to enable the area of the sub-LED having an electrode to be greater than the area of the sub-LED having no electrode (step S304). For example, as shown in FIG. 2, for the HV LED 2 according to one embodiment of the present invention, the total area of the HV LED 2 and the number of sub-LEDs (such as, C1 to C16) are calculated according to the light emission luminance and the operating voltage required by the customer. Next, the areas of the isolation trenches 22 between the sub-LEDs, the electrode areas and the areas of the series-connected conductive leads 21 between the sub-LEDs are subtracted from the total area. Then the difference obtained through the subtraction is divided by the number of the sub-LEDs, so as to calculate the effective light emission area of each of the sub-LEDs. After that, according to the effective light emission area, the area of a sub-LED C1 and C16 having an electrode and the area of a sub-LED C2 to C15 having no electrode are adjusted, so as to enable the area of the sub-LED C1 and C16 having an electrode to be greater than the area of the sub-LED C2 to C15 having no electrode. The aforementioned sub-LEDs C1 and C16 having an electrode may have different conductive type, such as, the electrode of the sub-LED C1 is a P-type electrode and the electrode of the sub-LED C16 is an N-type electrode. Alternatively, the electrode of the sub-LED C1 is an N-type electrode, and the electrode of the sub-LED C16 is a P-type electrode. Moreover, the electrode area of the electrodes of the sub-LEDs C1 and C16 may be a geometric area, and likewise, the area of each of the sub-LEDs may also be a geometric area. The geometric area includes a circular area or a polygonal area. The plurality of sub-LEDs C1 to C16 may be arranged in a matrix, but the present invention is not limited thereto. In this embodiment, the electrode areas of the sub-LEDs C1 and C16, the areas of the isolation trenches 22 between all the sub-LEDs, and the areas of the series-connected conductive leads 21 between all the sub-LEDs may be subtracted from the total area of the sub-LEDs C1 to C16, and then the difference obtained through the subtraction is divided by the number of the sub-LEDs C1 to C16, so as to obtain the effective light emission area of each of the sub-LEDs. Therefore, the effective light emission area of each of the sub-LEDs having no electrode may be obtained by subtracting the area of a series-connected conductive lead 21 from the area of each of the sub-LEDs having no electrode. The effective light emission area of each of the sub-LEDs having no electrode plus the area of the series-connected conductive lead 21 and the electrode area are equal to the adjusted area of the sub-LED having an electrode. Further, the proportion of the area of the series-connected conductive lead 21 of each sub-LED is low, and the areas of the series-connected conductive leads 21 on all the sub-LEDs may be designed to be the same, so the design may be simplified to enable all the sub-LEDs having no electrode to have the same area, and the area of the sub-LED having an electrode is equal to the sum of the area of the sub-LED having no electrode plus the electrode area.

Furthermore, if the length and the width of the conventional HV LED 1 are respectively set as X and Y, the conventional HV LED 1 includes n sub-LEDs, and the electrode area of the P-type electrode and the N-type electrode is set as a, the effective light emission area of a sub-LED with a P electrode or an N electrode is smaller than the effective light emission area of other sub-LEDs without any P electrode or N electrode by a proportion of [a/(X*Y/n)]*100%, resulting in different current densities of all the sub-LEDs and shortened service life of the conventional HV LED 1. In other words, for example, if the area of the chip of the HV LED in the size of 45 mil is 1140 μm×1140 μm, the HV LED is designed into 16 sub-LEDs, and the electrode has an diameter of 100 μm (it should be noted that, at this embodiment, the electrode takes a circular area as an example), the effective light emission area of the sub-LEDs C1 and C16 with a P electrode or an N electrode is smaller than that of other sub-LEDs C2 to C15 having no electrode by [(50*50*3.14)/(1140*1140/16)]*100%=9.7%. Therefore, it can be known that, when the conventional 45-mil HV LED is designed to have 16 sub-LEDs and the areas of all the sub-LEDs are the same, the effective light emission area of the sub-LED C1 and C16 having an electrode is smaller than that of the sub LEDs C2 to C15 having no electrode by 9.7%, so that the current density of C1 and C16 is higher than that of C2 to C15 by 9.7%, thereby shortening the service life of C1 and C16.

However, as far as the HV LED of the present invention is concerned, at first, the total electrode area 2a of the P electrode and the N electrode, the area m of the isolation trenches 22 between the sub-LEDs and the area q of the series-connected conductive leads 21 are subtracted from the area X*Y of the HV LED. Then the difference obtained through the subtraction is divided by the number n of the sub-LEDs, so as to obtain the effective light emission area b of each sub-LED (as shown in the following formula (1)). In certain embodiments, the area of the series-connected conductive leads 21 in each of the sub-LEDs C1 to C16 is the same, i.e., q/n. In certain embodiments, portions of the series-connected conductive leads 21 that cross the isolation trenches are very small comparing to the area of the sub-LEDs, and thus are neglectable. Accordingly, the area of C1 having an electrode and the area of C16 having an electrode are respectively added with the electrode area a and the area of respectively series-connected conductive leads q/n, so as to obtain the actual area c of C1 and C16 (as shown in formula (2)). Therefore, the current density may be averaged, so as to prolong the service life of the HV LED.

b=[(X*Y)−2a−m−q]/n (1)

c=[(X*Y)−2a−m−q]/n+a+q/n=[X*Y+(n−2)a−m]/n (2)

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments are chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A method for fabricating a high voltage light emitting diode (HV LED), comprising:
calculating a total area of the HV LED according to a predetermined light emission luminance;
calculating a number of sub-LEDs according to a predetermined operating voltage;
subtracting, from the total area, areas of isolation trenches between the sub-LEDs, electrode areas and areas of series-connected conductive leads between the sub-LEDs, and then dividing the difference obtained through the subtraction by the number of the sub-LEDs, so as to calculate an effective light emission area of each of the sub-LEDs; and
according to the effective light emission area, adjusting an area of a sub-LED having an electrode and an area of a sub-LED having no electrode, so as to enable the area of the sub-LED having an electrode to be greater than the area of the sub-LED having no electrode.

2. The method according to claim 1, wherein the electrode is a P-type electrode or an N-type electrode.

3. The method according to claim 1, wherein the sub-LEDs are arranged in a matrix.

4. The method according to claim 1, wherein the area of each of the sub-LEDs having no electrode minus the area of a series-connected conductive lead on the sub-LED is equal to the effective light emission area of the sub-LED.

5. The method according to claim 1, wherein the effective light emission area of each of the sub-LEDs plus the area of a series-connected conductive lead on the sub-LED and the electrode area is equal to the adjusted area of the sub-LED having an electrode.

6. The method according to claim 1, wherein all the sub-LEDs are connected in series to each other.

7. The method according to claim 1, wherein the HV LED comprises a sub-LED having a P-type electrode and a sub-LED having an N-type electrode.

8. The method according to claim 1, wherein the areas of the series-connected conductive leads on all the sub-LEDs are designed to be the same.

9. A high voltage light emitting diode (HV LED), comprising:
a plurality of sub-LEDs, comprising sub-LEDs having an electrode and sub-LEDs having no electrode,
wherein an area of a sub-LED having an electrode is greater than an area of a sub-LED having no electrode.

10. The HV LED according to claim 9, wherein the sub-LEDs are arranged in a matrix.

11. The HV LED according to claim 9, wherein the areas of the sub-LEDs having no electrode are equal.

12. The HV LED according to claim 9, wherein the area of a sub-LED having an electrode is equal to the sum of the area of a sub-LED having no electrode plus an area of the electrode.

13. The HV LED according to claim 9, wherein the HV LED comprises a sub-LED having a P-type electrode and a sub-LED having an N-type electrode.

14. The HV LED according to claim 9, wherein all the sub-LEDs are connected in series to each other.

15. The HV LED according to claim 9, further comprising isolation trenches between the sub-LEDs.

16. The HV LED according to claim 15, further comprising series-connected conductive leads between the sub-LEDs.

17. The HV LED according to claim 16, wherein the areas of the series-connected conductive leads on all the sub-LEDs are designed to be the same.

18. The HV LED according to claim 9, wherein an area of each of the sub-LEDs is a geometric area, comprising a circular area or a polygonal area.
